(19) United States
(12) Patent Application Publication
(10) Pub. No.: US 2015/0370391 A1
(43) Pub. Date: Dec. 24, 2015

(54) TOUCH DISPLAY DEVICE AND PROCESS FOR MANUFACTURING THE SAME

(71) Applicant: EverDisplay Optronics (Shanghai) Limited, Shanghai (CN)

(72) Inventors: Yujen CHEN, Shanghai (CN); Tsungyi SU, Shanghai (CN)

(21) Appl. No.: 14/584,271

(22) Filed: Dec. 29, 2014

(30) Foreign Application Priority Data
Jun. 20, 2014 (CN) 201410280123.5

(51) Int. Cl. G06F 3/041; H01L 51/56; H01L 27/32; G06F 3/047

(52) U.S. Cl. CPC G06F 3/0412; G06F 3/047; H01L 51/56; H01L 27/3276; H01L 27/323; G06F 2203/04103; H01L 2227/323

(57) ABSTRACT

A touch display device includes an encapsulating cover plate; a touch component positioned on the encapsulating cover plate and comprising at least one touch pattern and at least one wiring pad electrically connected with the at least one touch pattern; a TFT substrate, sealed together with the encapsulating cover plate by means of sealant; at least one OLED element formed on the TFT substrate; a touch wiring formed on the TFT substrate; at least one spacer positioned on the TFT substrate to keep the TFT substrate from the encapsulating cover plate for a distance; at least one conductivity layer formed on the at least one spacer to transmit signals from the touch component to the TFT substrate.

### CROSS-REFERENCE TO RELATED APPLICATIONS

This application claims benefits of Chinese Patent Application No. 201410280123.5, filed on Jun. 20, 2014 in the State Intellectual Property Office of China, the disclosure of which is incorporated herein by reference in its entirety.

### TECHNICAL FIELD

The disclosure relates to a touch display device and process of manufacturing the same, and, in particular, to a touch display device having touch components integrated in a display panel and its manufacturing process.

### BACKGROUND ART

Active matrix organic light emitting diode (AMOLED) as a new generation of the display technology has benefits, such as self illumination, wide view, high contrast, low power, rapid response speed, high resolution, full color and thinning tendency. The AMOLED hopefully becomes one of popular display technology in future.

At present, various electrical devices, such as mobile phones and tablet computers are widely provided with the touch display device for manipulating the devices trough touch sense. OLED touch display devices constituted by integrating the touch components with the OLED display panels have been put into the market.

The touch components are integrated into the OLED panel generally by two ways. As shown in FIG. 1, according to the first integration way, the touch display device comprises a TFT substrate 10, an OLED element 20 formed on the TFT substrate, an encapsulating cover plate 30, a sealant 70 between the TFT substrate 10 and the encapsulating cover plate 30 for sealing them together, a touch component 40 provided on the encapsulating cover plate 30, a protective cover 50 on the touch component 40, and a flexible printed circuit board (FPC) 60 electrically connected to the touch component 40. In such integration way, the touch component is adhered to the outer side of the encapsulating cover plate so that process and number of the components will be increased. And, since an additional protective cover 50 is required, the thickness of the touch device will be increased and thereby collides with request for thinning tendency of the touch device.

As shown in FIG. 2, according to the second integration way, the touch display device comprises a TFT substrate 10, an OLED element 20 formed on the TFT substrate 10, an encapsulating cover plate 30, a touch component 40 provided under the encapsulating cover plate 30, a sealant 70 between the TFT substrate 10 and the encapsulating cover plate 30 for sealing them together, and a flexible printed circuit board (FPC) 60 electrically connected to the touch component 40. In such integration way, as the touch components 40 are integrated in the inner sides of the encapsulating cover plate 30, it is required to perform the process of bonding the encapsulating cover plate after the process of bonding the FPC with the touch components. Additionally, the FPC bonding process is performed firstly, such that difficulty of bonding will be increased.

Therefore, a process for simplifying manufacturing process and/or having the thinner touch display device and integrating the touch components with OLED panels is needed.

The above information disclosed in this Background section is only for enhancement of understanding of the background of the disclosure and therefore it may contain information that does not form the prior art that is already known in this country to a person of ordinary skill in the art.

### SUMMARY OF INVENTION

Additional aspects and advantages will be set forth in part in the description which follows and, in part, will be apparent from the description, or may be learned by practice of the disclosure.

The present application provides a touch display device that may simplify manufacturing process and/or has smaller thickness.

According to one aspect of the disclosure, a touch display device comprises an encapsulating cover plate; a touch component positioned on the encapsulating cover plate and comprising at least one touch pattern and at least one wiring pad electrically connected with the at least one touch pattern; a TFT substrate, sealed together with the encapsulating cover plate by means of sealant; at least one OLED element formed on the TFT substrate; a touch wiring formed on the TFT substrate; at least one spacer positioned on the TFT substrate to keep the TFT substrate from the encapsulating cover plate for a distance; at least one conductivity layer formed on the at least one spacer to transmit signals from the touch component to the TFT substrate.

According to another aspect of the disclosure, a process for manufacturing a touch display device, wherein the touch display has a encapsulating cover plate provided with a touching component, and a TFT substrate sealed with the encapsulating cover plate and having at least one OLED element and a touch wiring formed therein, the process comprises the steps of:

forming at least one spacer on the TFT substrate, the at least one spacer is used to keep the TFT substrate from the encapsulating cover plate for a distance;

forming at least one conductivity layer on the at least one spacer to transmit signals from the touch component to the TFT substrate.

### BRIEF DESCRIPTION OF THE DRAWINGS

The foregoing and other features and advantages of the disclosure will be apparent to those skilled in the art in view of the following detailed description, taken in conjunction with the accompanying drawings.

FIG. 1 illustrates a manner of integrating the touch component to the OLED panel;

FIG. 2 illustrates another manner of integrating the touch component to the OLED;

FIG. 3 illustrates a structure of the touch display device according to an exemplary embodiment of the disclosure;

FIG. 4 illustrates the encapsulating cover plate and the touch component positioned on the encapsulating cover plate according to an exemplary embodiment of the disclosure;

FIG. 5 illustrates a way of forming the conductivity layer disconnected with the electrode on the spacer according to an exemplary embodiment of the disclosure.

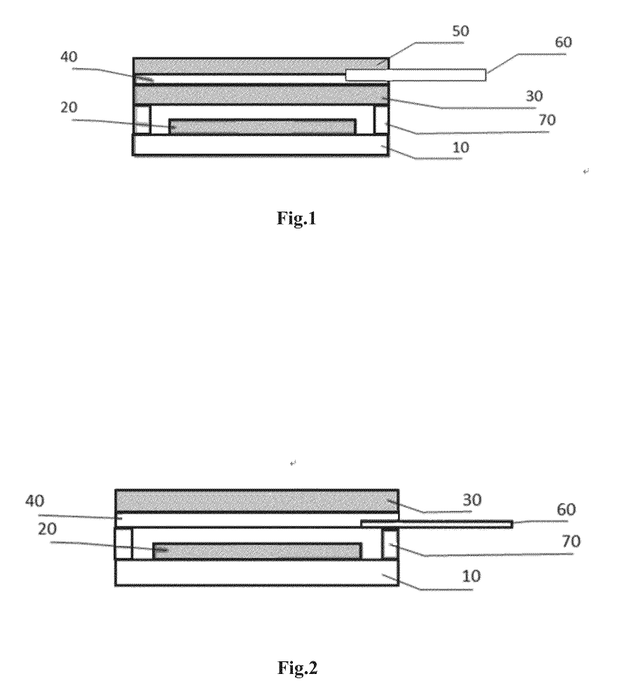

### DETAILED DESCRIPTION

Exemplary embodiments of the disclosure will now be described more fully with reference to the accompanying drawings, in which exemplary embodiments are shown. Exemplary embodiments of the disclosure may, however, be embodied in many different forms and should not be construed as being limited to the embodiments set forth herein; rather, these embodiments are provided so that this disclosure will be thorough and complete, and will fully convey the concept of exemplary embodiments to those skilled in the art. In the drawings, the thicknesses of layers and regions are exaggerated for clarity. Like reference numerals in the drawings denote like elements, and thus their description will be omitted.

The described features, structures, or/and characteristics of the disclosure may be combined in any suitable manner in one or more embodiments. In the following description, numerous specific details are disclosed to provide a thorough understanding of embodiments of the disclosure. One skilled in the relevant art will recognize, however, that the disclosure may be practiced without one or more of the specific details, or with other methods, components, materials, and so forth. In other instances, well-known structures, materials, or operations are not shown or described in detail to avoid obscuring aspects of the disclosure.

The disclosure provides a new way of integrating the touch component to the OLED panel to simplify the manufacturing process and/or to provide a touch display device with smaller thickness to meet the need for the thinning tendency of the touch display device. The embodiments will be illustrated with reference to the drawings.

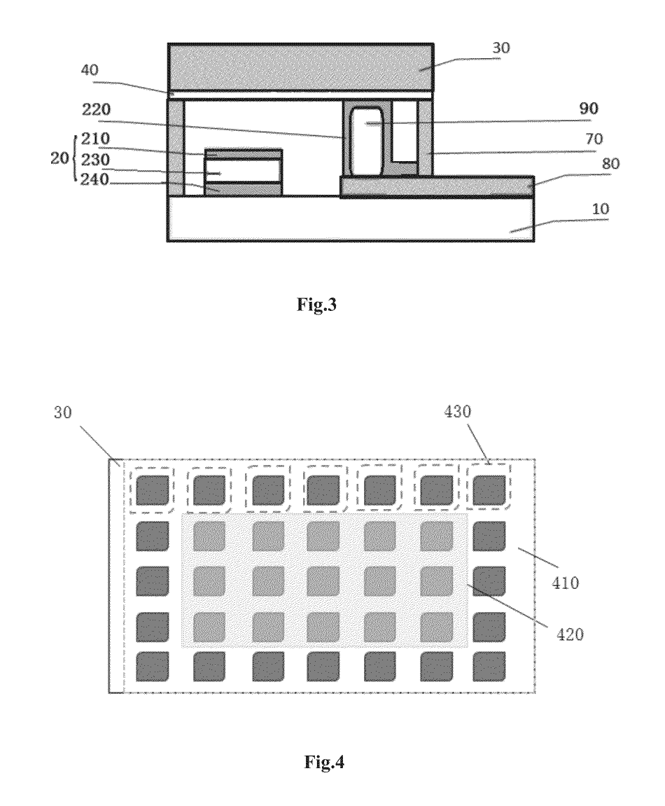

FIG. 3 shows a schematic structure of a touch display device according to the exemplary embodiment of the disclosure.

As shown in FIG. 3, the touch display device according to the exemplary embodiment includes a TFT substrate 10, at least one OLED element 20 formed on the TFT substrate, an encapsulating cover plate 30, a touch component 40 positioned under the encapsulating cover plate 30, a sealant 70 that is positioned between the TFT substrate 10 and the encapsulating cover plate 30 to seal them together, and at least one spacer 90 that is positioned between the TFT substrate 10 and the touch component 40. The spacer 90 is used to keep the TFT substrate 10 from the encapsulating cover plate 30 for a distance so as to provided the OLED element 20.

In the touch display device as shown in FIG. 3, signals from the touch component 40 are transmitted to the TFT substrate not by using FPC that bonds to the touch component 40 but by using a conductivity layer 220 formed at least on a part of the spacer 90. And, the signals are transmitted by using at least one touch wiring 80 on the TFT substrate so as to reduce risk and difficulty of subsequent procedure.

Specifically, as shown in FIG. 3, the OLED element 20 comprises an upper electrode 210, an organic layer 230 and a lower electrode 240. The upper electrode 210 may be a cathode or an anode. In the process of forming the upper electrode 210, a conductivity layer 220 is formed on the top surface and side surfaces of the spacer 90. The upper electrode 210 is disconnected with the conductivity layer 220, for example, by an etching process. The conductivity layer 220 is electrically connected with the touch component 40 and the touch wiring 80 positioned on the TFT substrate 10 to output the signals from the touch component 40 through the touch wiring 80.

The touch wiring 80 may be formed on the TFT substrate by the process of deposition, etching, etc. The touch wiring 80 may be formed simultaneously with the lower electrode of the OLED element 20, or may be formed separately.

The spacer 80 may be positioned on the touch wiring 80, as shown in FIG. 3. However, the disclosure is not limited thereto. For example, as shown in FIG. 5, the touch wiring 80 is positioned outside the spacer 90, i.e., at the side opposite to the OLED element 20.

As shown in FIG. 3, the spacer 90 may be a column. However, the disclosure is not limited thereto. For example, the spacer 90 may be a table. According to another embodiment, as shown in FIG. 5, the spacer 90 is a inclined column that is inclined towards the inner side of the TFT substrate.

The spacer 90 may be formed by photo-resist materials, but the disclosure is not limited thereto.

As shown in FIG. 3, the sealant 70 is provided between the TFT substrate 10 and the touch component 40. However, the disclosure is not limited thereto. According to another embodiment, size of the touch component 40 may be smaller than the size of the encapsulating cover plate 30, and the sealant 70 may be disposed at periphery of the touch component 40.

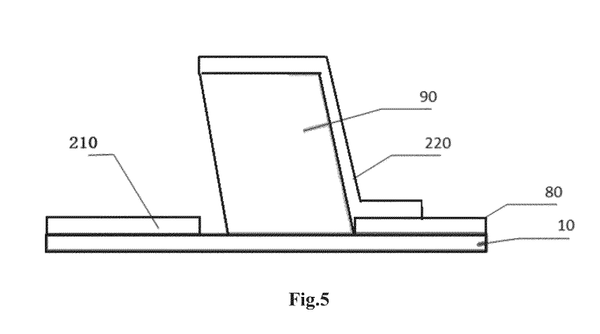

As shown in FIG. 4, the touch component 40 may comprises a transparent plate 410 and at least one touch pattern 420 and at least one wiring pad disposed on the transparent plate 410 and the wiring pad 430 electrically connected to the touch pattern 420. The touch pattern may be, for example, a transparent conductive pattern. An area where the touch pattern 420 is placed is an induction zone. The wiring pad 430 is positioned in a wiring zone. In this case, the touch component 40 may firstly adhere onto the encapsulating cover plate 30, as shown in FIG. 4. And then, the encapsulating cover plate 30 is assembled with the TFT substrate 10, and the wiring pad 430 faces the TFT substrate 10 and aligns the corresponding spacer 90, but the disclosure is not limited thereto. According to another embodiment, the touch component 40 may be directly formed on the encapsulating cover plate 30 but without using the transparent plate 410.

FIG. 5 shows a way of forming the conductivity layer 220 disconnected with the upper electrode 210 on the spacer 90 according to another embodiment.

As shown in FIG. 5, the side portion of the spacer 90 adjacent to the OLED element is inclined towards the inner side of the TFT substrate. For example, the spacer 90 is a inclined column that is inclined towards the inner side of the TFT substrate 10. The touch wiring 80 is positioned outside the spacer 90. The touch wiring 80 may be alternatively positioned under the spacer 90. When forming the upper electrode 210 of the OLED element 20 by the desposition process, the conductivity layer 220 is formed on the top portion and the side portion of the spacer 90. The conductivity layer 220 is electrically connected with the touch wiring 80. Due to the inclined structure of the spacer 90, when the upper electrode 210 is formed by the desposition process, the conductivity layer 220 is formed on the top portion and the external side portion of the spacer 90 but not formed on the internal side portion of the spacer 90 so that the conductivity layer 220 is disconnected with the upper electrode 210.

Hereinafter, a process of manufacturing the touch display device according to the exemplary embodiment will be described.

Preparing the encapsulating cover plate, and forming the touch component on the encapsulating cover plate. The touch component may comprise a transparent plate and at least one touch pattern such as transparent conductive pattern and at least one wiring pad disposed on the transparent plate, and the wiring pad electrically connected to the transparent conductive pattern. In this case, the touch component may be attached onto the encapsulating cover plate by the way of adhering. Alternatively, according to another embodiment, the touch component may be directly formed on the encapsulating cover plate and omitting the transparent plate.

Preparing the TFT substrate, and forming the OLED element, the touch wiring, the spacer and the conductivity layer that is positioned on the top portion and side portion of the spacer and is electrically connected with the touch wiring on the TFT substrate.

The OLED element comprises a lower electrode, an upper electrode and an organic layer between the upper electrode and the lower electrode. The upper electrode may be an anode or a cathode. The lower electrode may be a cathode or an anode.

The organic layer may comprises an overlapped cavity injection layer, cavity transporting layer, luminous layer, electron transporting layer and electron injection layer, but the disclosure is not limited thereto. The material and configuration of the OLED are well known by those skilled in the art, and thereby will not be repeated.

The touch wiring and the lower electrode may be positioned on the same layer and formed simultaneously, but the disclosure is not limited thereto.

The spacer may be formed using the photo-resist material through photolithography, developing, etc, but the disclosure is not limited thereto. The spacer may be a column or frustum. The position of at least a part of the spacers is corresponding to the wiring pads of the touch component. The spacer may be positioned on the touch wiring or inside the touch wiring.

The conductivity layer and the upper electrode may be positioned at the same layer, and formed simultaneously. For example, when forming the upper electrode, the conductivity layer is formed both on the top surface and the side surfaces of the spacer. The upper electrode may be disconnected with the conductivity layer, for example, through the etching process. The conductivity layer may be formed by the process as illustrated in FIG. 5.

The encapsulating cover plate may be assembled with the TFT substrate by means of the sealant, and the wiring pads is aligned with and contact the corresponding spacers.

Subsequently, other processes, such as connecting the drive IC or FPC, are performed but will not be repeated herein.

As above described, the touch display device according to some embodiments at least have one of the following advantages:

By using the conductivity layer on the spacer, the signals from the inner side of the encapsulating cover plate are transmitted to the TFT substrate, and the signals are output by using the touch wiring on the TFT substrate to reduce the risk and difficulty of the subsequent processes.

By performing the process of driving IC or FPC bonding after assembling the encapsulating cover plate and the TFT substrate, the assembling efficiency will be improved.

The existing AMOLED process is used without adding additional process or material.

By transmitting the signals from the inner side of the encapsulating cover plate to the TFT substrate, and outputting signals by using the touch wiring on the TFT substrate, the touch IC and the panel driving IC are integrated.

Although the disclosure has been described in reference to the above exemplary embodiments, it is to be understood that the disclosure will not be limited to the embodiments mentioned above, rather, the disclosure intents to cover all modification and equivalent arrangements within the spirit and scope of the appended claims. Exemplary embodiments have been specifically shown and described as above. It will be appreciated by those skilled in the art that the disclosure is not limited the disclosed embodiments; rather, all suitable modifications and equivalent which come within the spirit and scope of the appended claims are intended to fall within the scope of the disclosure.

What is claimed is:

1. A touch display device, comprising
an encapsulating cover plate;
a touch component, positioned on the encapsulating cover plate;
a TFT substrate, sealed together with the encapsulating cover plate by means of sealant;
at least one OLED element, formed on the TFT substrate;
a touch wiring, formed on the TFT substrate;
at least one spacer, positioned on the TFT substrate to keep the TFT substrate from the encapsulating cover plate for a distance;
at least one conductivity layer, formed on the at least one spacer to transmit signals from the touch component to the TFT substrate.

2. The touch display device according to claim 1, wherein side portions of the spacer adjacent to the OLED element are inclined towards an inner side of the TFT substrate to allow the conductivity layer to be formed only on the top and outside of the spacer.

3. The touch display device according to claim 2, wherein the OLED element comprises an upper electrode, a lower electrode and an organic layer positioned between the upper electrode and the lower electrode.

4. The touch display device according to claim 3, wherein the conductivity layer and the upper electrode are positioned on the same layer.

5. The touch display device according to claim 1, wherein the touch component comprises a touch pattern and a wiring pad electrically connected with the touch pattern, the touch pattern and the wiring pad are formed on the encapsulating cover plate with or without a transparent substrate formed therebetween.

6. The touch display device according to claim 2, wherein the touch component comprises a touch pattern and a wiring pad electrically connected with the touch pattern, the touch pattern and the wiring pad are formed on the encapsulating cover plate with or without a transparent substrate formed therebetween.

7. The touch display device according to claim 3, wherein the touch component comprises a touch pattern and a wiring pad electrically connected with the touch pattern, the touch pattern and the wiring pad are formed on the encapsulating cover plate with or without a transparent substrate formed therebetween.

8. The touch display device according to claim 7, wherein the conductivity layer is electrically connected to the wiring pad and the touch wiring so as to allow the conductivity layer to transmit the signals from the touch component to the TFT substrate.

9. The touch display device according to claim 1, wherein the spacer is directly disposed on the TFT substrate, and the touch wiring is positioned outside the spacer.

10. The touch display device according to claim 2, wherein the spacer is directly disposed on the TFT substrate, and the touch wiring is positioned outside the spacer.

11. A process for manufacturing a touch display device, wherein the touch display has an encapsulating cover plate provided with a touching component, and a TFT substrate sealed with the encapsulating cover plate and having at least one OLED element and a touch wiring formed therein, the process comprising the steps of:
forming at least one spacer on the TFT substrate, the at least one spacer is used to keep the TFT substrate from the encapsulating cover plate for a distance;
forming at least one conductivity layer on the at least one spacer to transmit signals from the touch component to the TFT substrate.

12. The process according to claim 11, wherein side portions of the spacer adjacent to the OLED element are inclined towards an inner side of the TFT substrate to allow the conductivity layer to be formed only on the top and outside of the spacer.

13. The process according to claim 11, wherein the OLED element comprises an upper electrode, a lower electrode and an organic layer positioned between the upper electrode and the lower electrode the conductivity layer and the upper electrode are positioned on the same layer.

14. The process according to claim 12, wherein the OLED element comprises an upper electrode, a lower electrode and an organic layer positioned between the upper electrode and the lower electrode the conductivity layer and the upper electrode are positioned on the same layer.

15. The process according to claim 11, wherein the touch component comprises a touch pattern and a wiring pad electrically connected with the touch pattern, the touch pattern and the wiring pad are formed on the encapsulating cover plate with or without a transparent substrate formed therebetween.

16. The process according to claim 12, wherein the touch component comprises a touch pattern and a wiring pad electrically connected with the touch pattern, the touch pattern and the wiring pad are formed on the encapsulating cover plate with or without a transparent substrate formed therebetween.

17. The process according to claim 13, wherein the touch component comprises a touch pattern and a wiring pad electrically connected with the touch pattern, the touch pattern and the wiring pad are formed on the encapsulating cover plate with or without a transparent substrate formed therebetween.

18. The process according to claim 17, wherein the conductivity layer is electrically connected to the wiring pad and the touch wiring so as to allow the conductivity layer to transmit the signals from the touch component to the TFT substrate.

19. The process according to claim 11, wherein the spacer is directly disposed on the TFT substrate, and the touch wiring is positioned outside the spacer.

20. The process according to claim 12, wherein the spacer is directly disposed on the TFT substrate, and the touch wiring is positioned outside the spacer.
